(19) United States
(12) Patent Application Publication
(10) Pub. No.: US 2014/0374697 A1
(43) Pub. Date: Dec. 25, 2014

(54) LIGHT-EMITTING ELEMENT, DISPLAY PANEL AND MANUFACTURING METHOD THEREOF

(71) Applicants: Yawei Liu, Shenzhen City (CN); Yi-fan Wang, Shenzhen City (CN)

(72) Inventors: Yawei Liu, Shenzhen City (CN); Yi-fan Wang, Shenzhen City (CN)

(73) Assignee: Shenzhen China Star Optoelectronics Technology Co., Ltd., Shenzhen, Guangdong (CN)

(21) Appl. No.: 14/006,314

(22) PCT Filed: Jun. 26, 2013
(86) PCT No.: PCT/CN2013/078023

§ 371 Date: Sep. 19, 2013

(30) Foreign Application Priority Data
Jun. 21, 2013 (CN) 2013102506615

(51) Int. Cl. H01L 27/32; H01L 51/56

(52) U.S. Cl. CPC H01L 27/3244; H01L 51/56
USPC 257/13; 438/28

(57) ABSTRACT

The present invention provides a light-emitting element, display panel and manufacturing method thereof. The light-emitting element includes a cathode and an anode, disposed oppositely; and a light-emitting layer, disposed between the cathode and the anode; the light-emitting layer comprising a mixture of organic material and blue quantum dot material. As such, the present invention improves the stability and luminance of the light-emitting element, and the light-emitting element has the advantages of ultra-thin, transparent and easy to bend.

### BACKGROUND OF THE INVENTION

1. Field of the Invention

The present invention relates to the field of displaying techniques, and in particular to a light-emitting element, display panel and manufacturing method thereof.

2. The Related Arts

Diode is a semiconductor electronic element and organic light-emitting diode (OLED) is a semiconductor electronic element able to emit light, also called organic electroluminescence display (OELD), OLED possesses the advantages of both CRT and LCD, and is heralded as the panel display and the third-generation display technique of the 21^{st} century, as well as an international research sensation.

The known technical approaches employed to realize the OLED colorization includes the following:
1. RGB light-emitting: this approach is only applicable to organic molecular material easy to sublimate.
2. White-light+RGB filters: this approach can utilize the mature LCD CF technology and requires no mask alignment bit; thus, this approach can greatly simplifies the deposition process so as to lower manufacturing cost and is applicable to manufacturing large-size high-resolution OLED. However, because the filters absorb the majority of the optical energy with only 30% of the light is able to penetrate, a high efficiency white-light material is required. Otherwise, the light-emitting element suffers the low efficiency. In general, only a small molecular OLED display is used.

Therefore, it is desirable to devise a light-emitting element with high stability and light-emission efficiency in the context of OLED colorization.

### SUMMARY OF THE INVENTION

The technical issue to be addressed by the present invention is to provide a light-emitting element, display panel and manufacturing method thereof, able to improve stability and luminance of the light-emitting element, as well as providing advantages of ultra-thin, transparent and flexible.

The present invention provides a light-emitting element, which comprises: a cathode and anode, disposed oppositely; a light-emitting layer, disposed between the cathode and the anode; the light-emitting layer comprising a mixture of organic material and blue quantum dot material, the blue quantum dot material being at least one, or mixed quantum dot of two or more of cadmium sulfide, cadmium selenide/zinc sulfide, and silicon nitride.

According to a preferred embodiment of the present invention, the mixed quantum dot is any one of a mixture of cadmium sulfide and cadmium selenide/zinc sulfide with quality ratio 1:1-3:1, a mixture of cadmium sulfide and silicon nitride with quality ratio 1:1-3:1, a mixture of cadmium selenide/zinc sulfide and silicon nitride with quality ratio 1:1-3:1, or a mixture of cadmium sulfide, cadmium selenide/zinc sulfide, and silicon nitride with quality ratio 4:(1-4):(1-4).

According to a preferred embodiment of the present invention, the organic material is any one of 4,4′,4″-tris(carbazole-9-yl)triphenylamine or 2,4,6-tris(carbazole-9-yl)-1,3,5-triazine.

According to a preferred embodiment of the present invention, the light-emitting element further comprises an electron transport layer; the electron transport layer is disposed between the light-emitting layer and the cathode; the light-emitting layer further comprises at least one of a hole injection layer or a hole transport layer, disposed between the light-emitting layer and the anode.

The present invention provides a display panel, which comprises: a plurality of pixel units, with each pixel unit comprising a plurality of sub-pixels, each sub-pixel corresponding to a color, each sub-pixel comprising a substrate and a translucent cover plate, disposed oppositely, and a light-emitting element; the light-emitting element being disposed between the substrate and the translucent cover plate; wherein the light-emitting element comprising; a cathode and anode, disposed oppositely; a light-emitting layer, disposed between the cathode and the anode; the light-emitting layer comprising a mixture of organic material and blue quantum dot material.

According to a preferred embodiment of the present invention, the blue quantum dot material is at least one of cadmium sulfide, cadmium selenide/zinc sulfide, and silicon nitride.

According to a preferred embodiment of the present invention, the blue quantum dot material is a mixed quantum dot of two or more of cadmium sulfide, cadmium selenide/zinc sulfide, and silicon nitride.

According to a preferred embodiment of the present invention, when the blue quantum dot material is a mixed quantum dot, the mixed quantum dot is any one of a mixture of cadmium sulfide and cadmium selenide/zinc sulfide with quality ratio 1:1-3:1, a mixture of cadmium sulfide and silicon nitride with quality ratio 1:1-3:1, a mixture of cadmium selenide/zinc sulfide and silicon nitride with quality ratio 1:1-3:1, or a mixture of cadmium sulfide, cadmium selenide/zinc sulfide, and silicon nitride with quality ratio 4:(1-4):(1-4).

According to a preferred embodiment of the present invention, the organic material is any one of 4,4′,4″-tris(carbazole-9-yl)triphenylamine or 2,4,6-tris(carbazole-9-yl)-1,3,5-triazine.

According to a preferred embodiment of the present invention, the light-emitting element further comprises an electron transport layer; the electron transport layer is disposed between the light-emitting layer and the cathode; the light-emitting layer further comprises at least one of a hole injection layer or a hole transport layer, disposed between the light-emitting layer and the anode.

According to a preferred embodiment of the present invention, each sub-pixel comprises a thin-film transistor (TFT) for controlling the light-emitting element corresponding to the sub-pixel to emit light and a corresponding color conversion layer; the color conversion layer is disposed on the light-emitting surface of the translucent cover plate for converting the light emitted by the light-emitting element into another color.

According to a preferred embodiment of the present invention, each pixel unit comprises a first sub-pixel correspondingly displaying red light; a second sub-pixel correspondingly displaying green light; and a third sub-pixel correspondingly displaying blue light.

According to a preferred embodiment of the present invention, the first sub-pixel correspondingly displaying red light comprises a red color conversion; a second sub-pixel correspondingly displaying green light comprises a green color conversion layer; and the red color conversion layer and the green color conversion layer are disposed at the light-emitting surface of the translucent cover plate.

According to a preferred embodiment of the present invention, the red color conversion layer is an europium-activated yttrium oxide layer; and the green color conversion layer is a cerium-, terbium-activated aluminate layer.

The present invention provides a manufacturing method of light-emitting element, which comprises: forming a transparent anode on a glass substrate; forming on the anode in the order of a hole injection layer and a hole transport layer; forming a light-emitting layer comprising a mixture material of organic material and blue quantum dot material on the hole transport layer; forming an electron transport layer on the light-emitting layer; and forming a transparent cathode on the electron transport layer.

According to a preferred embodiment of the present invention, the step of forming a light-emitting layer comprising a mixture material of organic material and blue quantum dot material on the hole transport layer comprises: mixing the grains of organic material and blue quantum dot material with a solvent, coating, and evaporating the solvent to form the light-emitting layer.

According to a preferred embodiment of the present invention, the manufacturing method further comprises: packaging the manufactured light-emitting element between a substrate and a translucent cover plate, and forming corresponding color conversion layer on the light-emitting surface of the translucent cover plate for converting color of light; and the step of forming a transparent anode on a glass substrate comprising: forming an anode and thin-film transistors connected to the anode for controlling the light-emitting element corresponding to each sub-pixel to emit light on the glass substrate.

The efficacy of the present invention is that to be distinguished from the state of the art. The material for the light-emitting layer of the light-emitting element of the present invention comprises a mixture of organic material and blue quantum dot material. Because the quantum dots have advantages of good stability, high efficiency, and long lifespan, the light-emitting element of the present invention shows better stability, high lighting efficiency, and suitable to large-current applications. By increasing the current, the brightness of the light-emitting element can be increased. The use of mixture of organic materials and blue quantum dots also effectively prevents the quantum dots from agglomeration and oxidation, and avoids fluorescence quenching caused by oxidation. In addition, the use of blue quantum dots as a luminescent material allows the manufacturing process of the light-emitting element to adopt printing technique so as to reduce the production cost, and is easier to fabricate on a flexible substrate than the known light-emitting elements, such as, LCD, LED. The thickness of the light-emitting layer is only a few hundred nanometers, so that the light-emitting element of the present invention provides the advantages of being ultra-thin, transparent, and easy to bend.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of a light-emitting element of an embodiment of the present invention;

FIG. 2 is a schematic view showing the structure of a sub-pixel of an embodiment of the display panel of the present invention;

FIG. 3 is a schematic view showing the structure of a pixel unit of an embodiment of the display panel of the present invention;

FIG. 4 is a schematic view showing the arrangement of a pixel unit of an embodiment of the display panel of the present invention;

FIG. 5 is a schematic view showing the driving circuit of a pixel unit of an embodiment of the display panel of the present invention; and

FIG. 6 is a flowchart showing the manufacturing method of a light-emitting element of the present invention.

### DETAILED DESCRIPTION OF THE PREFERRED EMBODIMENTS

Semiconductor nanocrystals (NCs) refer to the semiconductor nanocrystal dies with the size ranging 1-100 nm. Because the semiconductor nanocrystal is smaller than the exciton Bohr radius of its material, a strong quantum confinement effect is exhibited. The quasi-continuous band evolves into a structure of discrete levels similar to the molecular structure, which shows characteristics of a new material, also known as quantum dots (Quantum Dots, QDs). Because of the external excitation energy (photoluminescence, electroluminescence, cathodoluminescence, etc.), electron transitions from the ground state to the excited state. The excited electrons and holes may form excitons. Electron-hole recombination occurs, and then the final relaxation to the ground state follows. The excess energy released through recombination and relaxation processes, the radiative recombination may send photons. Therefore, the present embodiment utilizes this feature of quantum dot to provide a light-emitting element, with light-emitting layer comprising blue quantum dot material. The blue quantum dot material is a quantum dot material able to emit blue light.

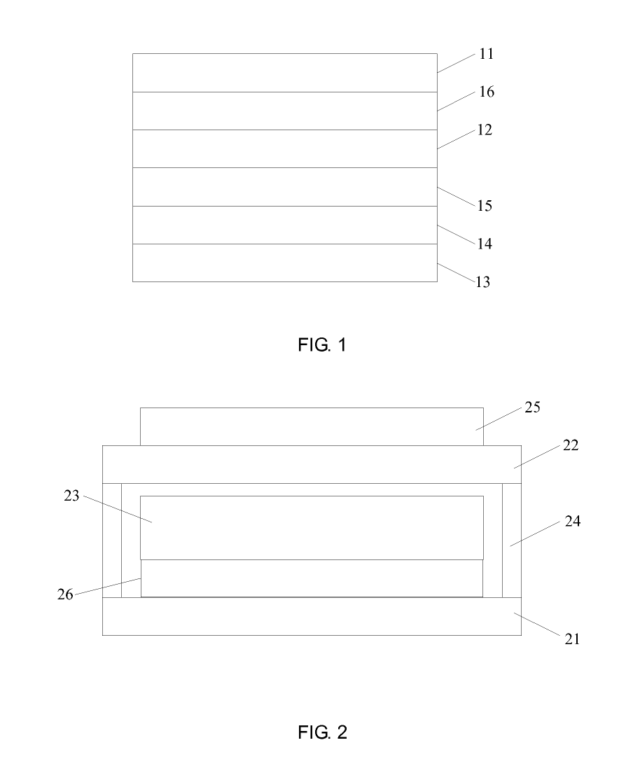

Referring to FIG. 1, FIG. 1 is a schematic view showing the structure of a light-emitting element of an embodiment of the present invention. The light-emitting element of the instant embodiment comprises: a cathode 11 and an anode 13, disposed oppositely; a light-emitting layer 12, disposed between the cathode 11 and the anode 13; the light-emitting layer 12 comprising a mixture of organic material and blue quantum dot material.

In the instant embodiment, the blue quantum dot material is at least one of cadmium sulfide, cadmium selenide/zinc sulfide, and silicon nitride.

When the blue quantum dot material is a mixture of two or more quantum dot materials, the mixture ratio of the respective quantum dot materials will directly affect the stability, the uniformity of light-emission and light-emission efficiency of the light-emitting element. After a long research, the present invention discloses a mixture where each material and respective ratio can complement one another to achieve optimal performance. For example, when the blue quantum dot material using a mixture of ZnCdS and CdSe/ZnS quantum dots, a mixing ratio of 1:1-3:1 of ZnCdS and CdSe/ZnS in accordance with the quality is better, and preferably 2:1. When the blue quantum dot material using a mixture of ZnCdS and SiN4 quantum dots, a mixing ratio of 1:1-3:1 of ZnCdS and SiN4 in accordance with the quality is better, and preferably 2.5:1. When the blue quantum dot material using a mixture of CdSe/ZnS and SiN4 quantum dots, a mixing ratio of 1:1-3:1 of CdSe/ZnS and SiN4 in accordance with the quality is better, and preferably 2:1. When the blue quantum dot material using a mixture of ZnCdS, CdSe/ZnS and SiN4 quantum dots, a mixing ratio of 1:(1-4):(1-4) of ZnCdS:CdSe/ZnS:SiN4 in accordance with the quality is better, and preferably 4:1:2.

In the instant embodiment, the organic material is any organic material that can prevent the blue quantum dot material from agglomeration and oxidation, such as, any one of 4,4′,4″-tris(carbazole-9-yl)triphenylamine (TCTA) or 2,4,6-tris(carbazole-9-yl)-1,3,5-triazine (TRZ), wherein the structure of the TCTA material is

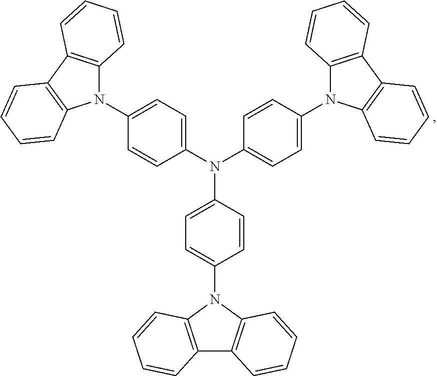 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

and the structure of the TRZ material is

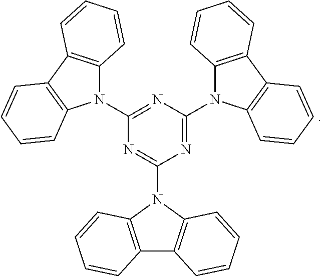 [SMILES: c1ccc2c(c1)c1ccccc1n2-c1nc(-n2c3ccccc3c3ccccc32)nc(-n2c3ccccc3c3ccccc32)n1]

Because quantum dots are nanoparticles, zero-dimensional materials, with high surfactants, and easy to agglomerate, which results in oxidation and causes fluorescence quenching. Through mixing organic materials and blue quantum dots, the agglomeration and oxidation of the quantum dots can be can effectively prevented.

Of course, in the instant embodiment, the material for light-emitting layer may use a quantum dot material that is capable of emitting blue light by itself. To prevent the agglomeration and oxidation of the blue quantum dots, when coating the light-emitting layer, a surfactant can be used with blue quantum dot materials for mixing in a solvent, and then volatile solvent is removed. The surfactant that can be used includes, but not limited to, stearic acid, zinc-based phosphine oxide, polymethyl methacrylate (PMMA) and so on.

Referring to FIG. 1, the light-emitting element of another embodiment of the present invention further comprises a hole injection layer 14, a hole transport layer 15 and an electron transport layer 16, wherein one of the hole injection layer 14 and the hole transport layer 15 may be optional. The hole injection layer 14 and the hole transport layer 15 are disposed between the light-emitting layer 12 and the anode 13. The electron transport layer 16 is disposed between the light-emitting layer and the cathode 11.

In the instant embodiment, the material for the hole injection layer 14 may be polyethylene 3,4-ethylenedioxythiophene thiophene (PEDOT), phthalocyanine blue (CuPc), and so on. The material for hole transport layer 15 may be polyethylene triphenylamine (poly-TPD), N,N′-diphenyl-N,N′-bis(3-methylphenyl)-1,1′-biphenyl-4,4′-diamine (TPD), 4,4′,4″-tris(N,N diphenyl amino)triphenylamine (TDATA), and so on. The material for the electron transport layer 16 may be a fluorescent dye such as 8-hydroxyquinoline aluminum (Alq3), and so on.

The light-emitting element in the instant embodiment may be a quantum dot light-emitting diode (QD-LED) Therefore, the light-emitting element of the present invention provides the following advantages over the organic light-emitting diode (OLED):
(1) The line width of the quantum dot light-emission is between 20-30 nm, which is narrower than the line width of organic light-emission half width (Full Width Half Maximum, FWHM), which is greater than 50 nm. As such, this is a key role for color purity of realistic image;
(2) Quantum dot exhibits better thermal stability than the organic materials. When the light-emitting element is in a high brightness or high current density, the Joule heat is the main reason for degradation of the element. Because of the excellent thermal stability, the light-emitting element based on quantum dot will exhibit long lifespan;
(3) Because the lifespan of the organic materials for the red, green and blue colors is different, the colors of the OLED display change with time. However, with the same kind of material to synthesize quantum dots of different sizes, because of the quantum confinement effect, the light-emission of the three primary colors can be achieved. The same kind of material may exhibit similar degradation of lifespan;
(4) The light-emitting element of the present invention based on the quantum dot can realize the emission of infrared light, and the emission wavelength of the organic material is generally less than 1 micron; and
(5) There is no spin statistics limitation on the quantum dots. The external quantum efficiency (EQE) may reach 100%. The EQE of the QD-LED can be expressed as: η_{Ext}=ηr*η_{INT}*η*η_{OUT}; wherein ηr is the probability of electron and hole exciton formation, η_{INT} is the internal quantum efficiency, i.e., the luminescence quantum yield (PLQY), η is the probability of radiative transition, η_{OUT} is external coupling efficiency. The limitation on the organic fluorescent dyes ηr is 25%, wherein the singlet and triplet states formation ratio is 1:3, and only the singlet exciton formation leads to light-emission. However, due to spin-orbit coupling, the ηr of the organic phosphorescent material is greater than 25%. It should be noted that the organic phosphorescent material causes degradation of the parent material. The η_{OUT} of a planar light-emitting element is about 20%, and can be external coupling efficiency can be increased through the micro-cavity structure. For the light-emitting element of the present invention, the η_{INT} can reach 100%, and when the energy levels of the electron and hole are appropriate, the ηr can also reach 100%.

The light-emitting element of the embodiment of the present invention may be organic light-emitting element (i.e., using mixture of organic material and blue quantum dot material as material for light-emitting layer), or purely inorganic element (i.e., using pure blue quantum dot material as material for light-emitting layer). The former can achieve high luminance and be manufactured by flexible process, the latter has higher stability because the material for the other layers of the light-emitting element, such as, hole injection layer, hole transport layer and electron transport layer is all inorganic material.

With the above description, the efficacy of the present invention is that to be distinguished from the state of the art. The material for the light-emitting layer of the light-emitting element of the present invention comprises a mixture of organic material and blue quantum dot material. Because the quantum dots have advantages of good stability, high efficiency, and long lifespan, the light-emitting element of the present invention shows better stability, high lighting efficiency, and suitable to large-current applications. By increasing the current, the brightness of the light-emitting element can be increased. The use of mixture of organic materials and blue quantum dots also effectively prevents the quantum dots from agglomeration and oxidation, and avoids fluorescence quenching caused by oxidation. In addition, the use of blue quantum dots as a luminescent material allows the manufacturing process of the light-emitting element to adopt printing technique so as to reduce the production cost, and is easier to fabricate on a flexible substrate than the known light-emitting elements, such as, LCD, LED. The thickness of the light-emitting layer is only a few hundred nanometers, so that the light-emitting element of the present invention provides the advantages of being ultra-thin, transparent, and easy to bend.

Based on the light-emitting element of above embodiment, the present invention further provides a display panel. Referring to FIG. 2, FIG. 2 is a schematic view showing the structure of a sub-pixel of an embodiment of the display panel of the present invention. The display panel of the instant embodiment comprises a plurality of pixel units. Each pixel unit comprises a plurality of sub-pixels, with each sub-pixel corresponding to a color, and each sub-pixel comprises a substrate 21 disposed opposite to a translucent cover plate 22, and a light-emitting element 23, wherein the light-emitting element 23 is disposed between the substrate 21 and the translucent cover plate 22. The substrate 21 and the translucent cover plate 22 are bonded together by a sealant 24 to seal and protect the light-emitting element 23.

In the instant embodiment, the sub-pixel of the present embodiment further comprises a thin-film transistor 26 to control the light-emitting element 23 corresponding to the sub-pixel and corresponding color conversion layer 25. The color conversion layer 25 is disposed on the light-emitting surface of the translucent cover plate 22 for the blue emitted from the light-emitting element 23 to be converted to another color through the color conversion layer 25. The thin-film transistor 26 is disposed between the substrate 21 and the light-emitting element 23, and connected respectively to the substrate 21 and the anode of the light-emitting element 23.

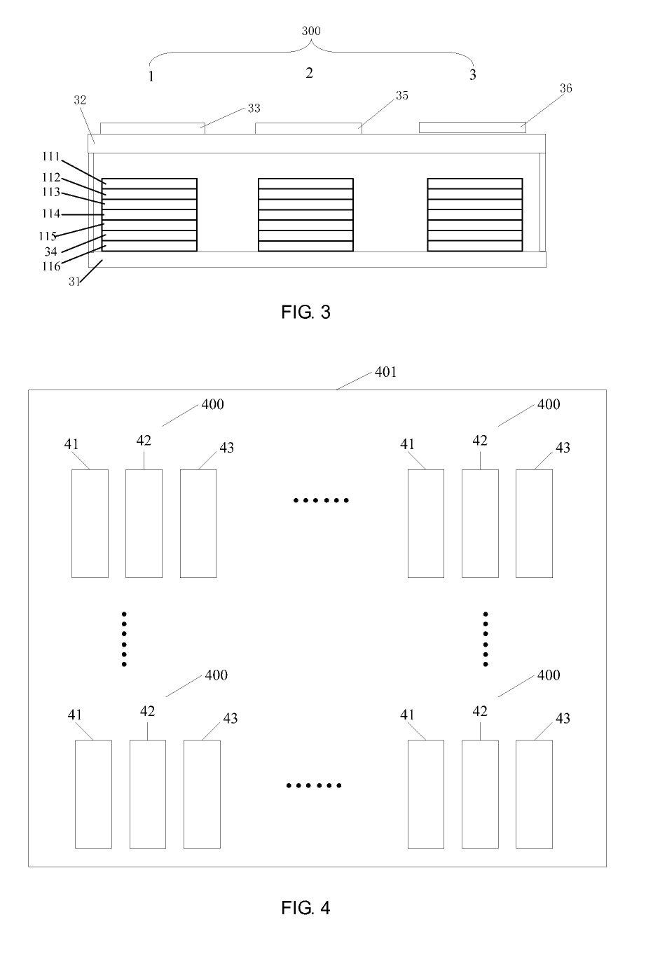

As an exemplar, referring to FIG. 3, FIG. 3 is a schematic view showing the structure of a pixel unit of an embodiment of the display panel of the present invention. In the instant embodiment, the pixel unit 300 may comprise a first sub-pixel 1 correspondingly displaying red light; a second sub-pixel 2 correspondingly displaying green light; and a third sub-pixel 3 correspondingly displaying blue light. Each sub-pixel comprises the substrate 31 and the translucent cover plate 32, disposed oppositely, and a thin-film transistor 34 for controlling the light-emitting element corresponding to the sub-pixel. Each sub-pixel further comprises the light-emitting element packaged between the substrate 31 and the translucent cover plate 32. The light-emitting element comprises the anode 116, the hole injection layer 115, the hole transport layer 114, the light-emitting layer 113, the electron transport layer 112 and transparent cathode 111, respectively (the detailed description of the structure of the light-emitting element is the same as the previous embodiment). The composition of each sub-pixel is similar and is not all labeled in the figure.

In the instant embodiment, the first sub-pixel 1 correspondingly displaying red light comprises a red color conversion layer 33; and the second sub-pixel 2 correspondingly displaying green light comprises a green color conversion layer 35. The red color conversion layer 33 and the green color conversion layer 35 are disposed respectively on the light-emitting surface of the translucent cover plate of the corresponding sub-pixel for converting the blue light emitted by the light-emitting element into respective red light and green light.

The red color conversion layer 33 may be a layer of red phosphor. The blue light emitted by the light-emitting element is converted into red light after the red color conversion layer. The red phosphor can be an europium-activated yttrium oxide (Y2O3: Eu3+). The green color conversion layer 35 may be a layer of green phosphor. The blue light emitted by the light-emitting element is converted into green light after the green color conversion layer. The green phosphor can be a cerium-, terbium-activated aluminate (MgAl11O19: Ce3+, Tb3+).

The third sub-pixel 3 correspondingly displaying blue light does not comprise a color conversion layer so that the blue light emitted by the light-emitting element directly passes through.

The instant embodiment uses red and green color conversion method (CCM) on a blue light-emitting element to achieve color display. Because the same color filter production technology can be used, compared with the RGB colorization technology, the instant embodiment improves the pixel density, and achieves a higher yield. Therefore, the technique of the present invention has a better prospect for applications.

Of course, the above is only an exemplar of the present invention. In fact, the display panel of the present invention may comprise only any one or two of the above first sub-pixel, second sub-pixel, and third sub-pixel. In addition, the first sub-pixel and the second sub-pixel are not necessarily corresponding to the red and green colors respectively. Different color conversion layers can be used so that the sub-pixels may correspond to other colors.

Referring to FIG. 4, FIG. 4 is a schematic view showing the arrangement of a pixel unit of an embodiment of the display panel of the present invention. A display panel 401 comprises a plurality of pixel units 400, and each pixel unit 400 comprises three sub-pixels, namely sub-pixel 41, sub-pixel 42, and the sub-pixel 43. The sub-pixels can be the first sub-pixel, the second sub-pixel and the third sub-pixel described in the above embodiment, or other sub-pixels. The order of the sub-pixels is not fixed and can be adjusted. Moreover, the arrangement of each pixel unit in the present embodiment is only exemplary; and another arrangement may also be adopted.

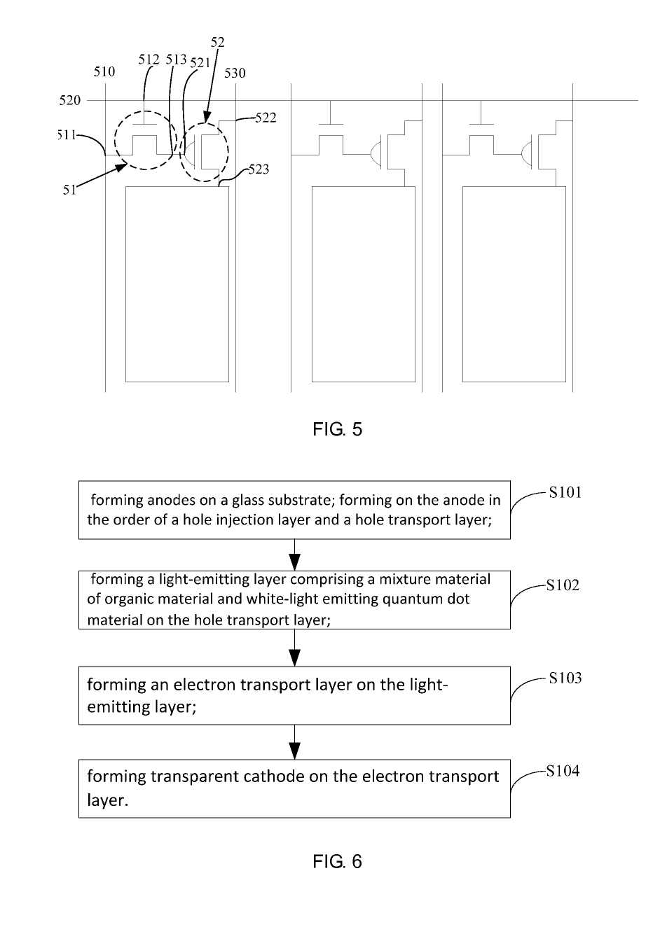

FIG. 5 is a schematic view showing the driving circuit of a pixel unit of an embodiment of the display panel of the present invention. As shown, the pixel unit of the instant embodiment comprises three sub-pixels, namely, the first sub-pixel, the second and the third sub-sub-pixel. Each sub-pixel is driven by two thin-film transistors (TFT), with one as switch TFT and the other as power-supply TFT. The first sub-pixel comprises a first switch TFT and a first power-supply TFT; the second sub-pixel comprises a second switch TFT and a second power-supply TFT; and the third sub-pixel comprises a third switch TFT and a third power-supply TFT. The sub-pixels of each column are connected to the same scan line 520 through respective TFT, and the sub-pixels of each row are connected to the same data line 510 through respective TFT.

The first switch TFT comprises a first source 511, a first gate 512 and a first drain 513, wherein the first source 511 is connected to the data line 510; the first gate 512 is connected to the scan line 520; the first drain 513 is connected to the gate 521 of the first power-supply TFT 52; the source 522 of the first power-supply TFT 52 is connected to the power line 530; the drain 523 of the first power-supply TFT 52 is connected to the anode of the light-emitting element of the first sub-pixel. The power line 530 supplies power to the first sub-pixel through the first power-supply TFT 52 to illuminate the sub-pixel. However, the switch TFT controls whether the power is supplied to the sub-pixel. The data line 510 and the scan line 520 drive the light-emitting element through the first switch TFT 51 and the first power-supply TFT 52 to emit the light so that the first sub-pixel displays the corresponding color, such as, red.

The second switch TFT and the second power-supply TFT, the third switch TFT and the third power-supply TFT are connected correspondingly as the first switch TFT and the first power-supply TFT, as described above, and the description will be omitted.

The data line 510 and the scan line 520 drive the light-emitting element through the second switch TFT and the second power-supply TFT to emit the light so that the second sub-pixel displays the corresponding color, such as, green.

The data line 510 and the scan line 520 drive the light-emitting element through the third switch TFT and the third power-supply TFT to emit the light so that the third sub-pixel displays the corresponding color, such as, blue.

The above driving circuit only illustrates 3 sub-pixels. For a pixel unit comprising more sub-pixels, the connection is similar to the above and the description will be omitted.

In addition, the present invention further provides a display panel, referring to FIG. 3. The display panel comprises a plurality of pixel units 300. Each pixel unit 300 at least comprises two sub-pixels, such as, sub-pixels 1, 3, or sub-pixels 2, 3. Each sub-pixel corresponds to a color, and each sub-pixel comprises a cathode 111, an anode 116 and a light-emitting layer 113. The light-emitting layer 113 is disposed between the cathode 111 and the anode 116. The light-emitting layer 113 comprises the blue quantum dot material. At least one sub-pixels such as, sub-pixel 3 in the figure) in each pixel unit emits blue light and at least another one sub-pixel (such as, sub-pixel 1 or 2 in the figure) comprises a color conversion layer (such as, color conversion layer 33, 35 in the figure) to convert the blue light emitted by the sub-pixel into a different color of light so that the light emitted by the pixel unit is a synthesis of blue light and a light of another color.

In other words, the display panel of the instant embodiment comprises at least two sub-pixels, wherein at least one sub-pixel emits blue light (i.e., the sub-pixel does not comprise a color conversion layer, such as, sub-pixel 3) and at least another one sub-pixel corresponds to a light of a color different from blue; that is, the sub-pixel comprises a color conversion layer to convert the blue light emitted by the light-emitting element into a different color of light, such as, sub-pixel 1 to emit red light or sub-pixel 2 to emit green light.

The composition and respective positional relation of the layers in the structure of the display panel of the instant embodiment can refer to the description of the above embodiment.

Referring to FIG. 6, FIG. 6 is a flowchart showing the manufacturing method of a light-emitting element of the present invention. The manufacturing method comprises the following steps:

Step S101: forming a transparent anode on a glass substrate; and forming on the anode in the order of a hole injection layer and a hole transport layer.

The formation of a layer of ITO transparent anode on the glass substrate may be accomplished by vapor deposition, coating, and so on. The hole injection layer and the hole transport layer sequentially formed on the transparent anode can be performed according to whether at least one of the hole injecting layer and the hole transport layer, or both layers are to be formed. The instant embodiment forms both the hole injecting layer and the hole injection layer. When forming the hole injection layer and hole transport layer, the hole transport layer is formed away from the anode and on top of the hole injecting anode layer. Deposition or coating may also be used for forming the hole injecting layer and the hole transport layer.

In the instant embodiment, the material for the hole injection layer may be PEDOT, CuPe, and so on; and the material for the hole transport layer may be poly-TPD, TPD, TDATA, and so on.

Step S102: forming a light-emitting layer comprising a mixture material of organic material and blue quantum dot material on the hole transport layer.

In the instant embodiment, the blue quantum dot material is at least one of cadmium sulfide, cadmium selenide/zinc sulfide, and silicon nitride.

When the blue quantum dot material is a mixture of two or more quantum dot materials, the mixture ratio of the respective quantum dot materials will directly affect the stability, the uniformity of light-emission and light-emission efficiency of the light-emitting element. After a long research, the present invention discloses a mixture where each material and respective ratio can complement one another to achieve optimal performance. For example, when the blue quantum dot material using a mixture of ZnCdS and CdSe/ZnS quantum dots, a mixing ratio of 1:1-3:1 of ZnCdS and CdSe/ZnS in accordance with the quality is better, and preferably 2:1. When the blue quantum dot material using a mixture of ZnCdS and SiN4 quantum dots, a mixing ratio of 1:1-3:1 of ZnCdS and SiN4 in accordance with the quality is better, and preferably 2.5:1. When the blue quantum dot material using a mixture of CdSe/ZnS and SiN4 quantum dots, a mixing ratio of 1:1-3:1 of CdSe/ZnS and SiN4 in accordance with the quality is better, and preferably 2:1. When the blue quantum dot material using a mixture of ZnCdS, CdSe/ZnS and SiN4 quantum dots, a mixing ratio of 1:(1-4):(1-4) of ZnCdS:CdSe/ZnS:SiN4 in accordance with the quality is better, and preferably 4:1:2.

In the instant embodiment, the organic material is any organic material that can prevent the blue quantum dot material from agglomeration and oxidation, such as, any one of 4,4′,4″-tris(carbazole-9-yl)triphenylamine (TCTA) or 2,4,6-tris(carbazole-9-yl)-1.3,5-triazine (TRZ), wherein the structure of the TCTA material is

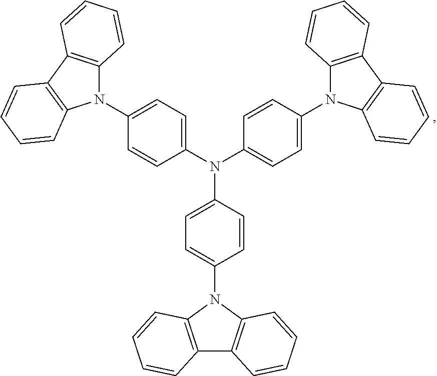 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

and the structure of the TRZ material is

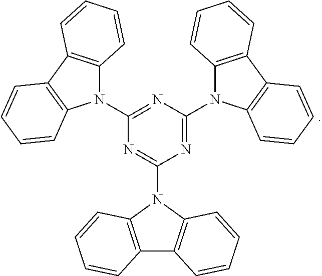 [SMILES: c1ccc2c(c1)c1ccccc1n2-c1nc(-n2c3ccccc3c3ccccc32)nc(-n2c3ccccc3c3ccccc32)n1]

Because quantum dots are nanoparticles, zero-dimensional materials, with high surfactants, and easy to agglomerate, which results in oxidation and causes fluorescence quenching. Through mixing organic materials and blue quantum dots, the agglomeration and oxidation of the quantum dots can be can effectively prevented.

One of the approaches to forming light-emitting layer in the instant embodiment is to mix the grains of the organic material and blue quantum dot material with a solvent. Then the mixed solution is coated on the hole transport layer and the volatile solvent evaporates to form the light-emitting layer.

In another embodiment, the material for light-emitting layer may use a quantum dot material that is capable of emitting blue-light by itself. To prevent the agglomeration and oxidation of the quantum dots, when coating the light-emitting layer, a surfactant can be used with blue quantum dot materials for mixing in a solvent, and then volatile solvent is removed to form the light-emitting layer. The surfactant that can be used includes, but not limited to, stearic acid, zinc-based phosphine oxide, polymethyl methacrylate (PMMA) and so on.

Step S103: forming an electron transport layer on the light-emitting layer.

In the step of forming an electron transport layer on the light-emitting layer, the material for the electron transport layer may be fluorescent dye compounds, such as, 8-hydroxyquinoline aluminum (Alq3), and so on.

Step S104: forming transparent cathode on the electron transport layer.

In the step of forming transparent cathode on the electron transport layer, the transparent cathode may be formed by deposition or coating process.

Further, when applying the light-emitting element of the present invention to a display panel, the manufacturing method of the present invention further comprises: packaging the manufactured light-emitting element between a substrate and a translucent cover plate, and forming corresponding color conversion layer on the light-emitting surface of the translucent cover plate; and the step of forming anodes on a glass substrate comprising: forming anodes and thin-film transistors connected to the anodes for controlling the light-emitting element corresponding to each sub-pixel to emit light on the glass substrate.

In the instant embodiment, the color conversion layer may be a layer of phosphor. For example, the red phosphor can be an europium-activated yttrium oxide (Y2O3: Eu3 +). The green phosphor can be a cerium-, terbium-activated aluminate (MgAl11O19: Ce3+, Tb3+). The green color conversion layer 35 may be a layer of green phosphor. The blue light emitted by the light-emitting element is converted by the color conversion layer into a color of light corresponding to the color of the phosphor.

With the above description, it should be noted that the material for the light-emitting layer of the light-emitting element of the present invention comprises a mixture of organic material and blue quantum dot material. Because the quantum dots have advantages of good stability, high efficiency, and long lifespan, the light-emitting element of the present invention shows better stability, high lighting efficiency, and suitable to large-current applications. By increasing the current, the brightness of the light-emitting element can be increased. The use of mixture of organic materials and white-light emitting quantum dots also effectively prevents the quantum dots from agglomeration and oxidation, and avoids fluorescence quenching caused by oxidation. In addition, the use of white-light emitting quantum dots as a luminescent material allows the manufacturing process of the light-emitting element to adopt printing technique so as to reduce the production cost, and is easier to fabricate on a flexible substrate than the known light-emitting elements, such as, LCD, LED. The thickness of the light-emitting layer is only a few hundred nanometers, so that the light-emitting element of the present invention provides the advantages of being ultra-thin, transparent, and easy to bend.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A light-emitting element, which comprises:
a cathode and an anode, disposed oppositely;
a light-emitting layer, disposed between the cathode and the anode; the light-emitting layer comprising a mixture of organic material and blue quantum dot material, the blue quantum dot material being at least one, or mixed quantum dot of two or more of cadmium sulfide, cadmium selenide/zinc sulfide, and silicon nitride.

2. The light-emitting element as claimed in claim 1, wherein:
the mixed quantum dot is any one of a mixture of cadmium sulfide and cadmium selenide/zinc sulfide with quality ratio 1:1-3:1, a mixture of cadmium sulfide and silicon nitride with quality ratio 1:1-3:1, a mixture of cadmium selenide/zinc sulfide and silicon nitride with quality ratio 1:1-3:1, or a mixture of cadmium sulfide, cadmium selenide/zinc sulfide, and silicon nitride with quality ratio 4:(1-4):(1-4).

3. The light-emitting element as claimed in claim 1, wherein:
the organic material is any one of 4,4′,4″-tris(carbazole-9-yl)triphenylamine or 2,4,6-tris(carbazole-9-yl)-1,3,5-triazine.

4. The light-emitting element as claimed in claim 1, wherein:
the light-emitting element further comprises an electron transport layer; the electron transport layer is disposed between the light-emitting layer and the cathode;
the light-emitting layer further comprises at least one of a hole injection layer or a hole transport layer, disposed between the light-emitting layer and the anode.

5. A display device, which comprises: a plurality of pixel units, with each pixel unit comprising a plurality of sub-pixels, each sub-pixel corresponding to a color, each sub-pixel comprising a substrate and a translucent cover plate, disposed oppositely, and a light-emitting element; the light-emitting element being disposed between the substrate and the translucent cover plate; wherein the light-emitting element comprising:
a cathode and anode, disposed oppositely;
a light-emitting layer, disposed between the cathode and the anode; the light-emitting layer comprising a mixture of organic material and blue quantum dot material.

6. The display device as claimed in claim 5, wherein:
the blue quantum dot material is at least one of cadmium sulfide, cadmium selenide/zinc sulfide, and silicon nitride.

7. The display device as claimed in claim 5, wherein:
the blue quantum dot material is a mixed quantum dot of two or more of cadmium sulfide, cadmium selenide/zinc sulfide, and silicon nitride.

8. The display device as claimed in claim 7, wherein:
when the blue quantum dot material is a mixed quantum dot, the mixed quantum dot is any one of a mixture of cadmium sulfide and cadmium selenide/zinc sulfide with quality ratio 1:1-3:1, a mixture of cadmium sulfide and silicon nitride with quality ratio 1:1-3:1, a mixture of cadmium selenide/zinc sulfide and silicon nitride with quality ratio 1:1-3:1, or a mixture of cadmium sulfide, cadmium selenide/zinc sulfide, and silicon nitride with quality ratio 4:(1-4):(1-4).

9. The display device as claimed in claim 5, wherein:
the organic material is any one of 4,4′,4″-tris(carbazole-9-yl) triphenylamine or 2,4,6-tris(carbazole-9-yl)-1,3,5-triazine.

10. The display device as claimed in claim 5, wherein:
the light-emitting element further comprises an electron transport layer; the electron transport layer is disposed between the light-emitting layer and the cathode;
the light-emitting layer further comprises at least one of a hole injection layer or a hole transport layer, disposed between the light-emitting layer and the anode.

11. The display device as claimed in claim 5, wherein:
each sub-pixel comprises a thin-film transistor (TFT) for controlling the light-emitting element corresponding to the sub-pixel to emit light and a corresponding color conversion layer; the color conversion layer is disposed on the light-emitting surface of the translucent cover plate for converting the light emitted by the light-emitting element into another color.

12. The display device as claimed in claim 5, wherein;
each pixel unit comprises a first sub-pixel correspondingly displaying red light; a second sub-pixel correspondingly displaying green light; and a third sub-pixel correspondingly displaying blue light.

13. The display device as claimed in claim 12, wherein:
the first sub-pixel correspondingly displaying red light comprises a red color conversion; a second sub-pixel correspondingly displaying green light comprises a green color conversion layer; and the red color conversion layer and the green color conversion layer are disposed at the light-emitting surface of the translucent cover plate.

14. The display device as claimed in claim 13, wherein;
the red color conversion layer is an europium-activated yttrium oxide layer; and the green color conversion layer is a cerium-, terbium-activated alum mate layer.

15. A manufacturing method of light-emitting element, which comprises:
forming a transparent anode on a glass substrate; forming on the transparent anode in the order of a hole injection layer and a hole transport layer;
forming a light-emitting layer comprising a mixture material of organic material and blue quantum dot material on the hole transport layer;
forming an electron transport layer on the light-emitting layer; and
forming transparent cathode on the electron transport layer.

16. The manufacturing method as claimed in claim 15, wherein:
the step of forming a light-emitting layer comprising a mixture material of organic material and blue quantum dot material on the hole transport layer comprises: mixing the grains of organic material and blue quantum dot material with a solvent, coating, and evaporating the solvent to form the light-emitting layer.

17. The manufacturing method as claimed in claim 15, further comprising:
packaging the manufactured light-emitting element between a substrate and a translucent cover plate, and forming corresponding color conversion layer for converting light color on the light-emitting surface of the translucent cover plate: and
the step of forming a transparent anode on a glass substrate comprising: forming an anode and thin-film transistors connected to the anode for controlling the light-emitting element corresponding to each sub-pixel to emit light on the glass substrate.
